(19) United States
(12) Patent Application Publication
(10) Pub. No.: US 2009/0079506 A1
(43) Pub. Date: Mar. 26, 2009

(54) PHASE-LOCKED LOOP AND METHOD WITH FREQUENCY CALIBRATION

(75) Inventors: Ji-Hao WU, Tainan City (TW); Shen-Iuan Liu, Taipei City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL TAIWAN UNIVERSITY, Taipei (TW)

(21) Appl. No.: 11/950,186

(22) Filed: Dec. 4, 2007

(30) Foreign Application Priority Data
Sep. 26, 2007 (TW) 096135809

(51) Int. Cl. H03L 7/087; H03L 7/08; H03L 7/085

(52) U.S. Cl. 331/11

(57) ABSTRACT

A phase-locked loop including a phase-voltage conversion unit, a calibration unit, and an oscillation feedback unit is provided. The phase-voltage conversion unit receives a reference signal having a first frequency and a first phase, and a first feedback signal having a second frequency and a second phase, and produces a first adjusting signal based on the first frequency, the second frequency, and a phase difference between the first phase and the second phase. The calibration unit receives the reference signal and the first feedback signal, and produces a second adjusting signal based on a frequency difference between the first frequency and the second frequency through a binary search operation. The oscillation feedback unit receives the first adjusting signal and the second adjusting signal, and has a controllable capacitor array controlled by the second adjusting signal for producing a second feedback signal having a third phase locked to the first phase.

### FIELD OF THE INVENTION

The present invention relates to a phase-locked loop and method with frequency calibration, and more particularly to a phase-locked loop and method with frequency calibration for applying to wireless communication.

### BACKGROUND OF THE INVENTION

Please refer to FIG. 1, which is a schematic block diagram showing a circuit of a conventional phase-locked loop. As shown, the phase-locked loop 10 includes a phase-frequency detector 101, a charge pump 102, a loop filter 103, a voltage controlled oscillator 104, and a frequency-dividing unit 105.

The phase-frequency detector 101 receives a reference signal V_{REF1} and a feedback signal V_{DIV1}, wherein the reference signal V_{REF1}, has a reference frequency f_{REF1} and a reference phase Φ_{REF1}, and the feedback signal V_{DIV1} has a frequency f_{DIV1} and a phase Φ_{DIV1}. The phase-frequency detector 101 makes a comparison among the frequencies f_{REF1} and f_{DIV1}, and the phases Φ_{REF1} and Φ_{DIV1}, for producing a comparison result signal V_{COMP1} including information about a difference among the frequencies f_{REF1} and f_{DIV1}, and the phases Φ_{REF1} and Φ_{DIV1}.

The charge pump 102 receives the comparison result signal V_{COMP1} for producing a current signal I_{SIG1} corresponding to the difference. The loop filter 103 receives the current signal I_{SIG1} and converts the current signal I_{SIG1} for producing a voltage controlled signal V_{CTRL1}.

The voltage controlled oscillator 104 receives the voltage controlled signal V_{CTRL1} for producing an output signal V_{OUT1} having a frequency f_{OUT1}, wherein the frequency f_{OUT1} is proportional to the amplitude of the voltage controlled signal V_{CTRL1}. The frequency-dividing unit 105 receives the output signal V_{OUT1} and performs a frequency division operation a divisor of which is M for producing the feedback signal V_{DIV1}, wherein the frequency f_{DIV1} is 1/M times as large as the frequency f_{OUT1} The output signal V_{OUT1} is adjusted to stabilize due to the feedback mechanism of the frequency-dividing unit 105.

When the phase-locked loop is applied to a high-speed circuit, the design frequency is often difficult to be predicted due to deviation of the manufacturing process, so that the design difficulty of the voltage controlled oscillator and the frequency-dividing unit is increased. For instance, when the frequencies of the voltage controlled oscillator and the frequency-dividing unit deviate, the produced frequency-divisible range may not smoothly cover the adjustable range of the voltage controlled oscillator, which makes the phase-locked loop unable to be locked.

### SUMMARY OF THE INVENTION

It is an object of the present invention to provide a phase-locked loop and method with frequency calibration. An adjusting signal is produced by a binary search operation for controlling a controllable capacitor array of an oscillation feedback unit. Therefore, the effect reducing the required time of frequency calibration is accomplished.

It is therefore an aspect of the present invention to provide the phase-locked loop including a phase-voltage conversion unit, a calibration unit, and an oscillation feedback unit. The phase-voltage conversion unit receives a reference signal having a first frequency and a first phase, and a first feedback signal having a second frequency and a second phase, and produces a first adjusting signal based on the first frequency, the second frequency, and a phase difference between the first phase and the second phase. The calibration unit receives the reference signal and the first feedback signal, and produces a second adjusting signal based on a frequency difference between the first frequency and the second frequency through a binary search operation. The oscillation feedback unit receives the first adjusting signal and the second adjusting signal, and has a controllable capacitor array controlled by the second adjusting signal for producing a second feedback signal having a third phase locked to the first phase.

It is therefore another aspect of the present invention to provide the frequency calibration method on a phase-locked loop having a controllable capacitor array. The method includes the following steps. A first adjusting signal is produced based on a first frequency and a first phase of a reference signal, and a second frequency and a second phase of a first feedback signal. A second adjusting signal is produced based on a frequency difference between the first frequency and the second frequency through a binary search operation. An oscillation and a second feedback signal having a third phase locked to the first phase is produced.

The foregoing and other features and advantages of the present invention will be more clearly understood through the following descriptions with reference to the drawings, wherein:

### BRIEF DESCRIPTION OF THE DRAWINGS

FIG. 1 is a schematic block diagram showing a circuit of a conventional phase-locked loop;

FIG. 2 is a schematic block diagram showing a phase-locked loop according to the first embodiment of the present invention;

FIG. 3 is a schematic block diagram showing a phase-locked loop according to the second embodiment of the present invention;

FIG. 4 is a schematic diagram showing a circuit of a voltage controlled oscillator having a controllable capacitor array according to the second embodiment of the present invention;

FIG. 5 is a schematic diagram showing a circuit of a frequency pre-dividing unit having a controllable capacitor array according to the second embodiment of the present invention;

FIG. 6 is a schematic diagram showing a circuit of a controllable capacitor array according to the second embodiment of the present invention;

FIG. 7(a), FIG. 7(b), FIG. 7(c), and FIG. 7(d) are schematic diagrams showing a circuit of a frequency detector and three sets of waveforms thereof according to the second embodiment of the present invention;

FIG. 8(a), and FIG. 8(b) are schematic diagrams showing a circuit of a lock detector and a set of waveforms thereof according to the second embodiment of the present invention;

FIG. 9(a), and FIG. 9(b) are schematic diagrams showing a circuit of a reset controller and a set of waveforms thereof according to the second embodiment of the present invention;

FIG. 10(a), and FIG. 10(b) are schematic diagrams showing a circuit of a successive approximation register controller and an algorithm thereof according to the second embodiment of the present invention;

FIG. 11 is a schematic diagram showing a distribution of frequency bands of the phase-locked loop according to the second embodiment of the present invention; and

FIG. 12 is a schematic block diagram showing a phase-locked loop according to the third embodiment of the present invention.

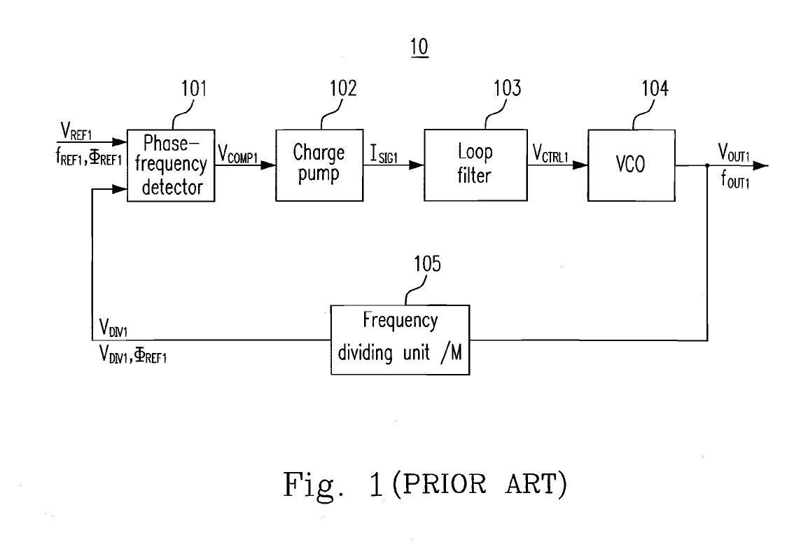

### DETAIL DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

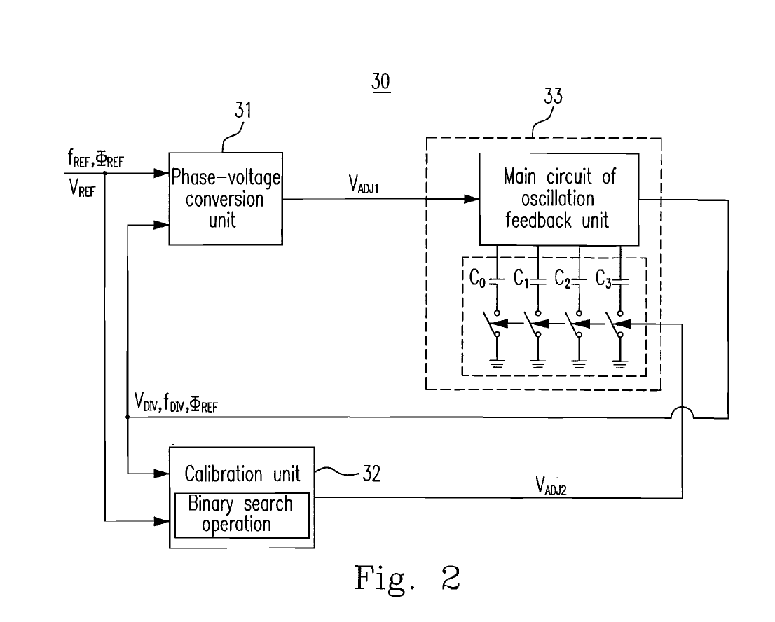

Please refer to FIG. 2, which is a schematic block diagram showing a phase-locked loop according to the first embodiment of the present invention. As shown, the phase-locked loop 30 includes a phase-voltage conversion unit 31, a calibration unit 32, and an oscillation feedback unit 33. The phase-voltage conversion unit 31 receives a reference signal V_{REF} and a first feedback signal V_{DIV}, wherein the reference signal V_{REF} has a reference frequency f_{REF} and a reference phase Φ_{REF}, and the first feedback signal V_{DIV} has a frequency f_{DIV} and a phase Φ_{DIV}. The phase-voltage conversion unit 31 produces a first adjusting signal V_{ADJ1} based on the frequency f_{REF}, the frequency f_{DIV}, and a phase difference between the phase Φ_{REF} and the second phase Φ_{DIV}.

The calibration unit 32 receives the reference signal V_{REF} and the first feedback signal V_{DIV}, and produces a second adjusting signal V_{ADJ2} based on a frequency difference between the frequency f_{REF} of the reference signal V_{REF} and the frequency f_{DIV} of the first feedback signal V_{DIV} through a binary search operation. The oscillation feedback unit 33 receives the first adjusting signal V_{ADJ1} and the second adjusting signal V_{ADJ2}, and has a controllable capacitor array 33A controlled by the second adjusting signal V_{ADJ2} for producing a second feedback signal having a phase locked to the phase Φ_{REF} of the reference signal V_{REF}. The second feedback signal is fed back to the phase-voltage conversion unit 31 and the calibration unit 32 and is produced for serving as the first feedback signal V_{DIV}.

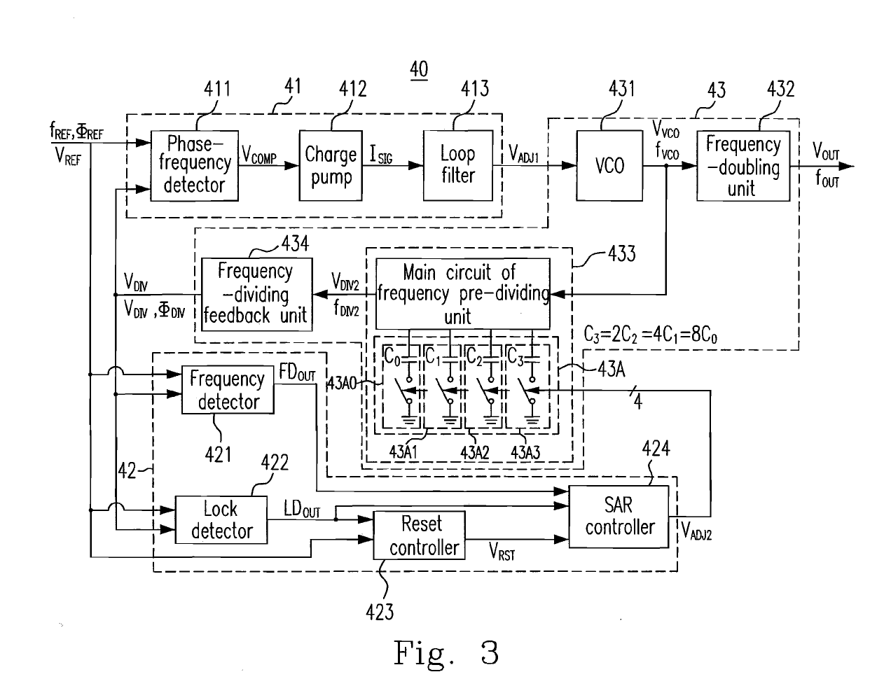

Please refer to FIG. 3, which is a schematic block diagram showing a phase-locked loop according to the second embodiment of the present invention. The circuit in FIG. 3 is an embodying configuration of the circuit in FIG. 2. As shown in FIG. 3, the phase-locked loop 40 includes a phase-voltage conversion unit 41, a calibration unit 42, and an oscillation feedback unit 43.

The phase-voltage conversion unit 41 includes a phase-frequency detector 411, a charge pump 412, and a loop filter 413. The phase-frequency detector 411 receives a reference signal V_{REF} and a first feedback signal V_{DIV}, wherein the reference signal V_{REF} has a reference frequency f_{REF} and a reference phase Φ_{REF}, and the first feedback signal V_{DIV} has a frequency f_{DIV} and a phase Φ_{DIV}. The phase-frequency detector 411 makes a comparison among the frequencies f_{REF} and f_{DIV}, and the phases Φ_{REF} and Φ_{DIV}, for producing a comparison result signal V_{COMP} including information about the frequencies f_{REF} and f_{DIV}, and a phase difference between the phases Φ_{REF} and Φ_{DIV}. The charge pump 412 receives the comparison result signal V_{COMP} for producing a current signal I_{SIG}. The loop filter 413 receives the current signal I_{SIG} and converts the current signal I_{SIG} for producing a first adjusting signal V_{ADJ1}, wherein there is a function relation between the amplitude of the first adjusting signal V_{ADJ1} and quantities of the frequencies f_{REF} and f_{DIV}, and a phase difference between the phase Φ_{REF} and the phase Φ_{DIV}.

The calibration unit 42 includes a frequency detector 421, a lock detector 422, a reset controller 423, and a successive approximation register controller 424. The frequency detector 421 receives the reference signal V_{REF} and the first feedback signal f_{DIV}, and compares the frequency f_{REF} of the reference signal V_{REF} with the frequency f_{DIV} of the first feedback signal V_{DIV} for producing a comparison result signal FD_{OUT} having a frequency difference between the frequency f_{REF} and the frequency f_{DIV}, and denoting the frequency f_{DIV} is greater than or less than the frequency f_{REF}. The lock detector 422 receives the reference signal V_{REF} and the first feedback signal V_{DIV}, and compares the phase Φ_{REF} of the reference signal V_{REF} with the phase Φ_{DIV} of the first feedback signal V_{DIV} for producing a lock result signal LD_{OUT} having a phase difference between the phase Φ_{REF} and the phase Φ_{DIV}, and denoting whether a time difference between the phase Φ_{REF} and the phase Φ_{DIV} is within a predetermined period.

The reset controller 423 receives the reference signal V_{REF} and the lock result signal LD_{OUT} for producing a reset signal V_{RST} based on the reference signal V_{REF} and the lock result signal LD_{OUT}. The reset signal V_{RST} is provided to the successive approximation register controller 424 reset to its initial state by a reset state of the reset signal V_{RST}. The successive approximation register controller 424 has N (N=4 in the present embodiment) shift registers (not shown in FIG. 3) with four output terminals, receives the comparison result signal FD_{OUT}, the lock result signal LD_{OUT} and the reset signal V_{RST}, and performs the binary search operation for producing four adjusting sub-signals of the second adjusting signal V_{ADJ2} at the four output terminals respectively, wherein the four adjusting sub-signals correspondingly control N (N=4 in the present embodiment) capacitor strings 43A0, 43A1, 43A2, and 43A3 of a controllable capacitor array 43A of the oscillation feedback unit 43, and form a digital adjusting value having four bits.

The oscillation feedback unit 43 includes a voltage controlled oscillator 431, a frequency-doubling unit 432, a frequency pre-dividing unit 433, and a frequency-dividing feedback unit 434. The voltage controlled oscillator 431 receives the first adjusting signal V_{ADJ1} for producing a first object signal V_{VCO} having a frequency f_{VCO} depending on the amplitude of the first adjusting signal V_{ADJ1}. The frequency-doubling unit 432 receives the first object signal V_{VCO} for producing a second object signal V_{OUT} having a frequency f_{OUT} twice higher than the frequency f_{VCO} of the first object signal V_{VCO}.

The frequency pre-dividing unit 433 receives the first object signal V_{VCO} and pre-divides the frequency f_{VCO} of the first object signal V_{VCO} for producing an intermediate signal V_{DIV2}, wherein a relation of a first division ratio is formed by the frequency f_{DIV2} of the intermediate signal V_{DIV2} relative to the frequency f_{VCO} of the first object signal V_{VCO}. The frequency-dividing feedback unit 434 receives the intermediate signal V_{DIV2} and pre-divides the frequency V_{DIV2} of the intermediate signal V_{DIV2} for producing the second feedback signal, wherein a relation of a second division ratio is formed by the frequency of the second feedback signal relative to the frequency f_{DIV2} of the intermediate signal V_{DIV2}. Besides, the second feedback signal is fed back to the phase-voltage conversion unit 41 and the calibration unit 42 and is produced for serving as the first feedback signal V_{DIV}.

One of the oscillation devices, the voltage controlled oscillator 431, the frequency pre-dividing unit 433, and the frequency-dividing feedback unit 434, includes the controllable capacitor array 43A. When the voltage controlled oscillator 431 includes the controllable capacitor array 43A, the frequency f_{VCO} of the first object signal V_{VCO} further depends on the second adjusting signal V_{ADJ2}. As shown in FIG. 3, when the frequency pre-dividing unit 433 includes the controllable capacitor array 43A, the frequency V_{DIV2} of the intermediate signal V_{DIV2} further depends on the second adjusting signal V_{ADJ2}. When the frequency-dividing feedback unit 434 includes the controllable capacitor array 43A, the frequency of the second feedback signal further depends on the second adjusting signal V_{ADJ2}.

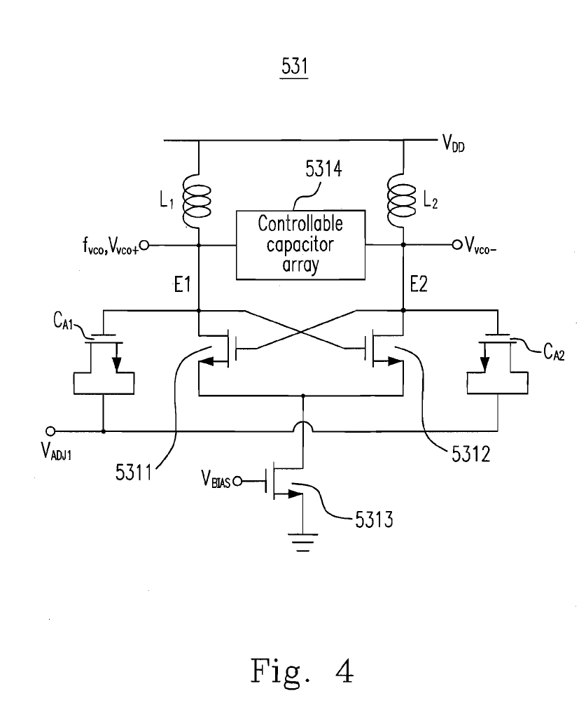

Please refer to FIG. 4, which is a schematic diagram showing a circuit of a voltage controlled oscillator having a controllable capacitor array according to the second embodiment of the present invention. As shown, the voltage controlled oscillator 531 includes two inductors L₁ and L₂, three transistors 5311, 5312, and 5313, two varactors C_{A1} and C_{A2}, and a controllable capacitor array 5314. The common connection terminal, of the drain and the source, of the varactor C_{A1} is coupled with the common connection terminal, of the drain and the source, of the varactor C_{A2}, and receives the first adjusting signal V_{ADJ1}. The controllable capacitor array 5314 is connected in parallel with two output terminals E1 and E2 of the voltage controlled oscillator 531, and the first object signal V_{VCO} is output between the two output terminals E1 and E2.

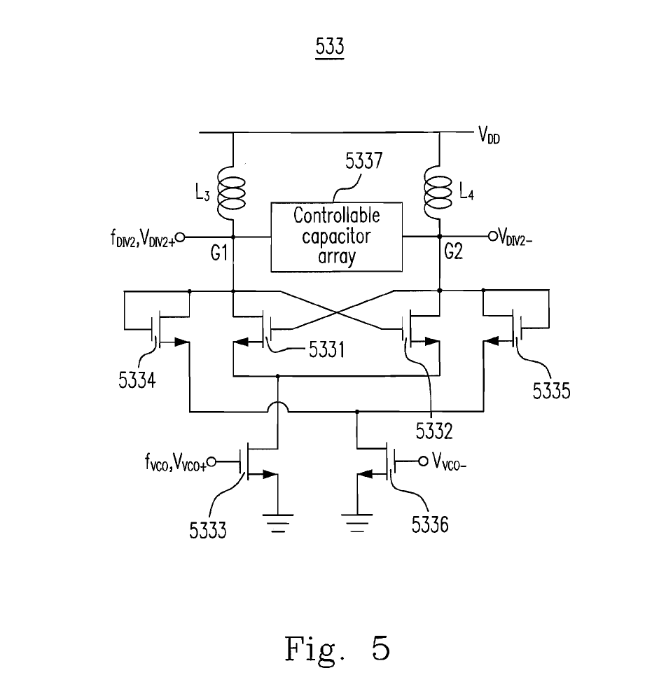

Please refer to FIG. 5, which is a schematic diagram showing a circuit of a frequency pre-dividing unit having a controllable capacitor array according to the second embodiment of the present invention. As shown, the frequency pre-dividing unit 533 is, e.g., a differential injection-locked frequency divider a standard divisor of which is 2. The frequency pre-dividing unit 533 includes two inductors L₃ and L₄, six transistors 5331, 5332, 5333, 5334, 5335, and 5336, and a controllable capacitor array 5337, wherein the controllable capacitor array 5337 is connected in parallel with two output terminals G1 and G2 of the frequency pre-dividing unit 533. The first object signal V_{VCO} is received between the gate of the transistor 5333 and the gate of the transistor 5336 of the frequency pre-dividing unit 533, and the intermediate signal V_{DIV2} is output between the two output terminals G1 and G2.

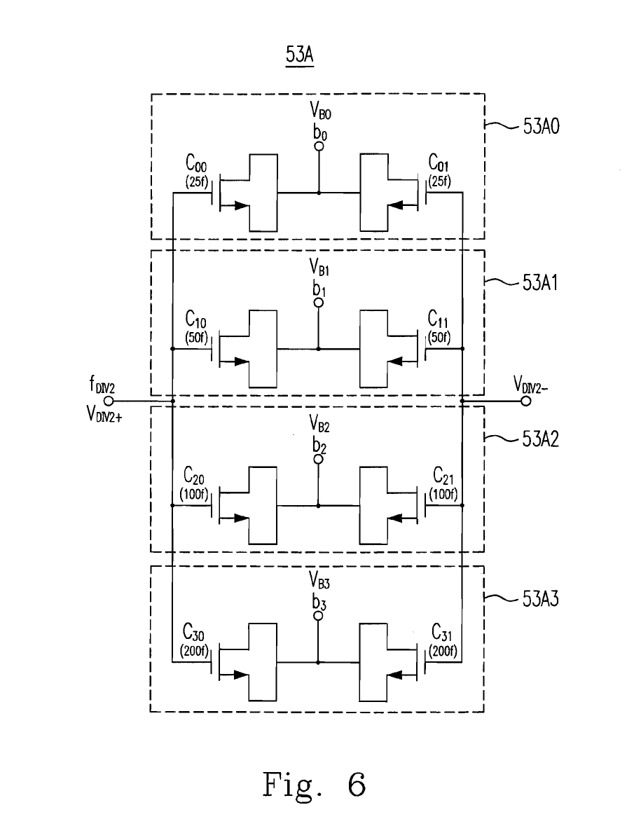

Please refer to FIG. 6, which is a schematic diagram showing a circuit of a controllable capacitor array according to the second embodiment of the present invention. As shown, the controllable capacitor array 53A includes four (N=4) capacitor strings 53A3, 53A2, 53A1, and 53A0 correspondingly controlled by four adjusting sub-signals V_{B3}, V_{B2}, V_{B1}, and V_{B0} of the second adjusting signal V_{ADJ2}, wherein the four adjusting sub-signals V_{B3}, V_{B2}, V_{B1}, and V_{B0} form a digital adjusting value having four bits b₃, b₂, b₁, and b₀. Each (such as 53A0) of the four capacitor strings 53A3, 53A2, 53A1, and 53A0 includes a pair of varactors (such as C₀₀ and C₀₁) face-to-face connected in series, wherein a common cathode connection point of the pair of the varactors (such as C₀₀ and C₀₁) receives a corresponding first adjusting sub-signal (such as V_{B0}) of the four adjusting sub-signals V_{B3}, V_{B2}, V_{B1}, and V_{B0} and each (such as C₀₀) of the varactors (such as C₀₀ and C₀₁) is a transistor having a drain terminal and a source terminal commonly connected to a common cathode connection point.

Four single-side capacitance values (such as 200f of C₃₀, 100f of C₂₀, 50f of C₁₀, and 25f of C₀₀) of the four capacitor strings 53A3, 53A2, 53A1, and 53A0 form a distribution of geometric series with a common ratio of 2. The most significant bit b₃ of the four bits b₃, b₂, b₁, and b₀ corresponds to the capacitor string 53A3, having the maximum value (such as 200f of C₃₀) of the four single-side capacitance values (such as 200f of C₃₀, 100f of C₂₀, 50f of C₁₀, and 25f of C₀₀), of the four capacitor strings 53A3, 53A2, 53A1, and 53A0. The least significant bit b₀ of the four bits b₃, b₂, b₁, and b₀ corresponds to the capacitor string 53A0, having the minimum value (such as 25f of C₀₀) of the four single-side capacitance values (such as 200f of C₃₀, 100f of C₂₀, 50f of C₁₀, and 25f of C₀₀), of the four capacitor strings 53A3, 53A2, 53A1, and 53A0.

When an adjusting sub-signal (such as V_{B2}) of the four adjusting sub-signals V_{B3}, V_{B2}, V_{B1}, and V_{B0} selects a capacitor string (such as 53A2) corresponding thereto, the frequency of the second feedback signal decreases in comparison with a state of the capacitor string (such as 53A2) when not selected. When the adjusting sub-signal (such as V_{B2}) of the four adjusting sub-signals V_{B3}, V_{B2}, V_{B1}, and V_{B0} does not select the capacitor string (such as 53A2) corresponding thereto, the frequency of the four adjusting sub-signals increases in comparison with a state of the capacitor string (such as 53A2) when selected.

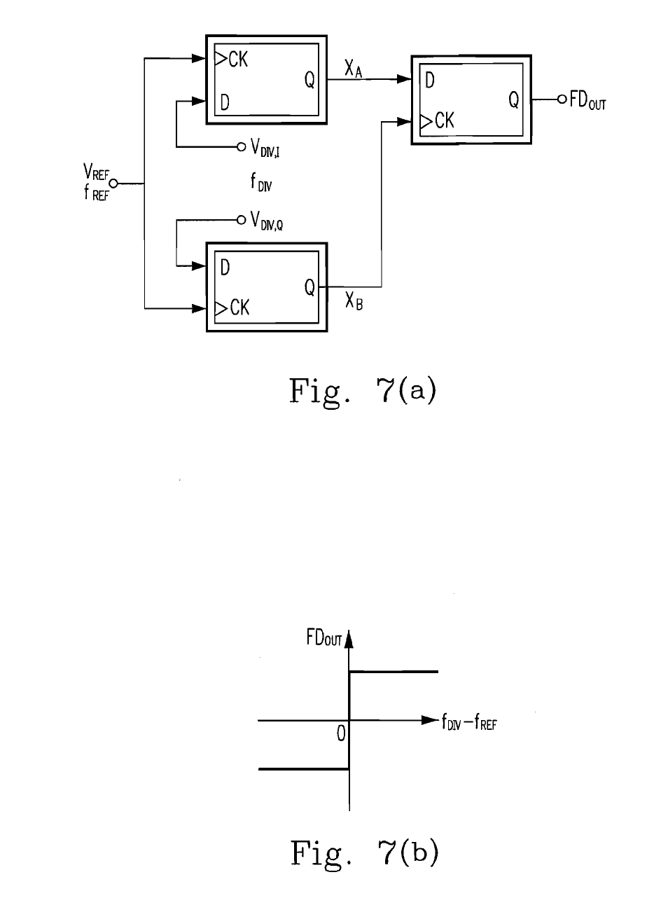

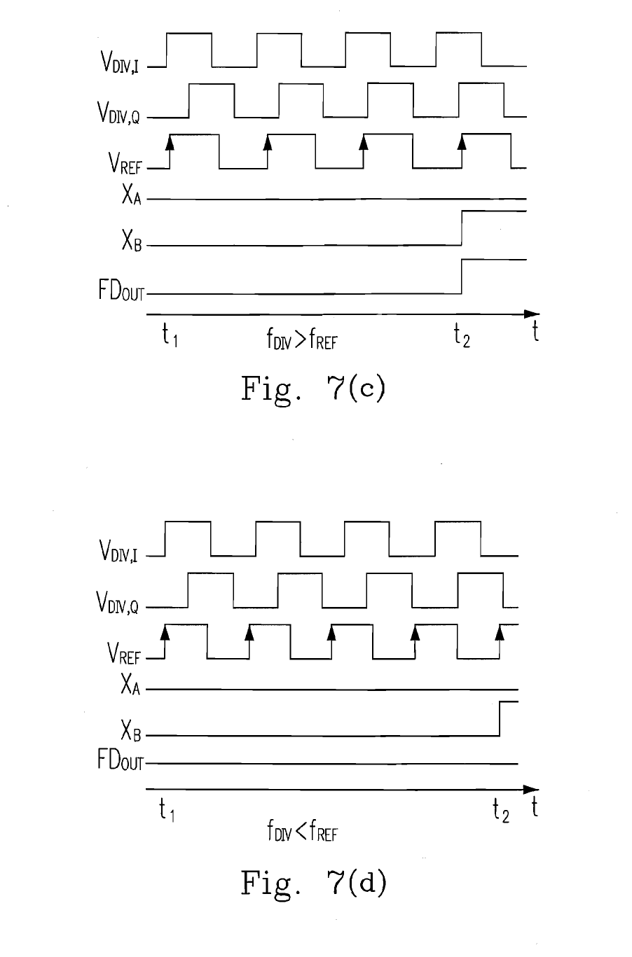

Please refer to FIG. 7(a), FIG. 7(b), FIG. 7(c), and FIG. 7(d), which are schematic diagrams showing a circuit of a frequency detector and three sets of waveforms thereof according to the second embodiment of the present invention. As shown, the frequency detector 521 including three flip-flops 5211, 5212, and 5213, receives a feedback sub-signal V_{DIV,I} and a feedback sub-signal V_{DIV,Q} of the first feedback signal V_{DIV} and the reference signal V_{REF} for producing a comparison result signal FD_{OUT}, wherein there is a phase difference 90° between the feedback sub-signal V_{DIV,I} and the feedback sub-signal V_{DIV,Q}. Comparing the amplitude of the frequency f_{DIV} of the first feedback signal V_{DIV} with that of the frequency f_{REF} of the reference signal V_{REF} is begun at time t₁. The comparison result signal FD_{OUT} is produced at time t₂. When the frequency f_{DIV} is greater than the frequency f_{REF} and after time t₂, the comparison result signal FD_{OUT} becomes at a high logical level. When the frequency f_{DIV} is less than the frequency f_{REF} and after time t₂, the comparison result signal FD_{OUT} becomes at a low logical level.

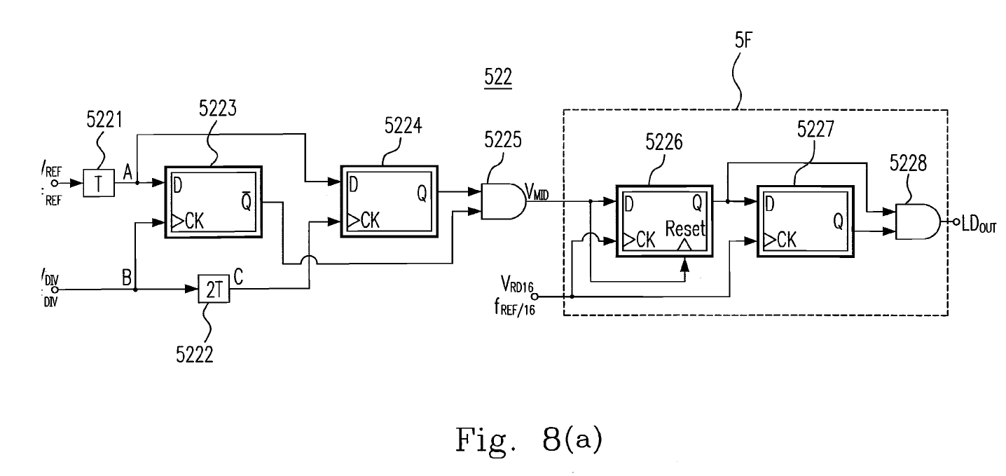

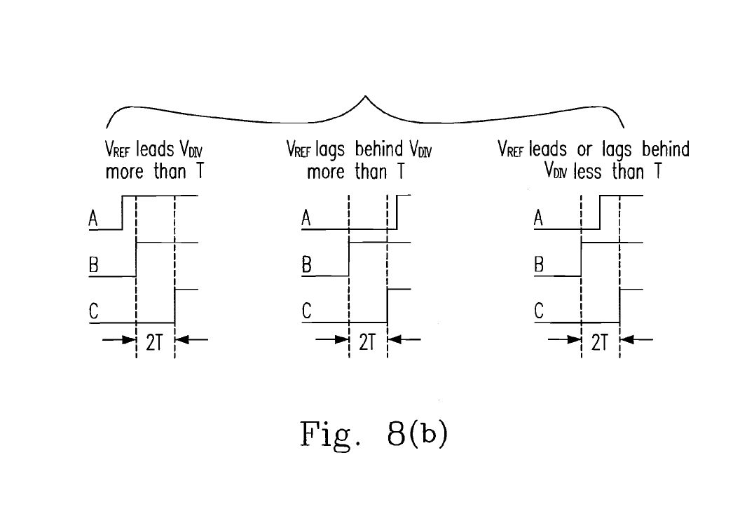

Please refer to FIG. 8(a), and FIG. 8(b), which are schematic diagrams showing a circuit of a lock detector and a set of waveforms thereof according to the second embodiment of the present invention. As shown, the lock detector 522 includes a delay line 5221, a delay line 5222, two flip-flops 5223, and 5224, an AND gate 5225, and a deglitch unit 5F. After the reference signal V_{REF} having a frequency f_{REF} is delayed a period T by the delay line 5221, the delayed reference signal is provided to the data input terminal D of the flip-flop 5223 and the data input terminal D of the flip-flop 5224. The clock input terminal CK of the flip-flop 5223 receives the first feedback signal V_{DIV}. After the first feedback signal V_{DIV} is delayed a period 2T by the delay line 5222, the delayed first feedback signal is provided to the clock input terminal CK of the flip-flop 5224, which makes the output terminal of the AND gate 5225 produce a signal V_{MID}. In order to avoid a glitch phenomenon of the signal V_{MID} in the lock transient period, the deglitch unit 5F receives a frequency-dividing signal V_{RD16} of the reference signal V_{REF} and the signal V_{MID} for producing the lock result signal LD_{OUT}, wherein the deglitch unit 5F includes two flip-flops 5226 and 5227, and an AND gate, and the frequency of the frequency-dividing signal V_{RD16} is f_{REF}/16.

When the reference signal V_{REF} leads the first feedback signal V_{DIV} more than the period T or the reference signal V_{REF} lags behind the first feedback signal V_{DIV} more than the period T, the lock result signal LD_{OUT} becomes at a low logical level for denoting the lock result signal LD_{OUT} being in a non-lock state. When the reference signal V_{REF} leads the first feedback signal V_{DIV} less than the period T or the reference signal V_{REF} lags behind the first feedback signal V_{DIV} less than the period T, the lock result signal LD_{OUT} becomes at a high logical level for denoting the lock result signal LD_{OUT} being in a lock state.

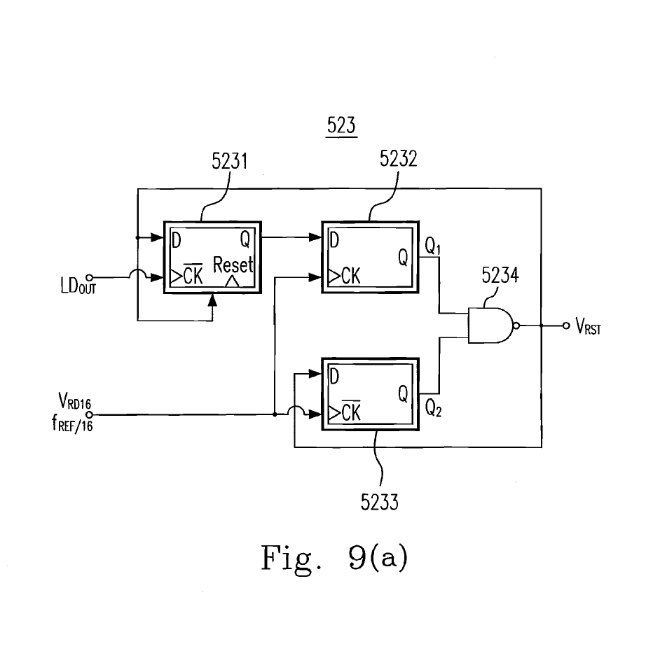

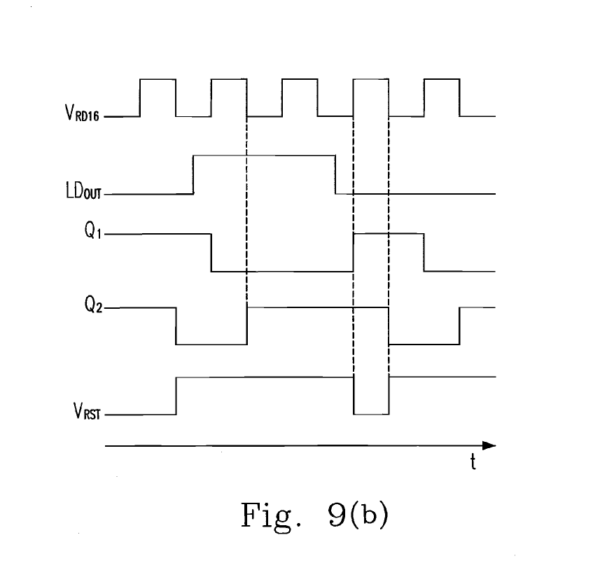

Please refer to FIG. 9(a), and FIG. 9(b), which are schematic diagrams showing a circuit of a reset controller and a set of waveforms thereof according to the second embodiment of the present invention. As shown, the reset controller 523 including three flip-flops 5231, 5232, and 5233, and a NAND gate 5234, receives a frequency-dividing signal V_{RD16} of the reference signal V_{REF} and the lock result signal LD_{OUT} for producing the reset signal V_{RST}, wherein the frequency of the frequency-dividing signal V_{RD16} is f_{REF}/16. When the reset signal V_{RST} is at a high logical level, the reset signal V_{RST} is in a non-reset state. When the reset signal V_{RST} is at a low logical level, the reset signal V_{RST} is in a reset state. As shown in FIG. 9(b), after the lock result signal LD_{OUT} becomes in the non-locked state, the period of the first high-level pulse corresponds to the period of the reset state. That is, when the reset signal V_{RST} is in the reset state, the reset controller 523 inverts the reset signal V_{RST} to be in the non-reset state through the trigger of the frequency-dividing signal V_{RD16} converted from the reference signal V_{REF}.

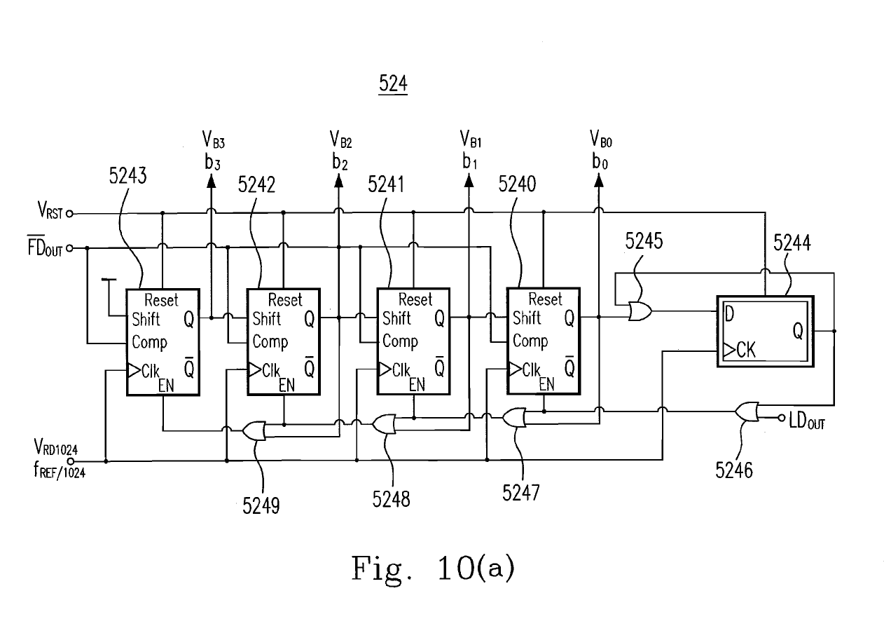

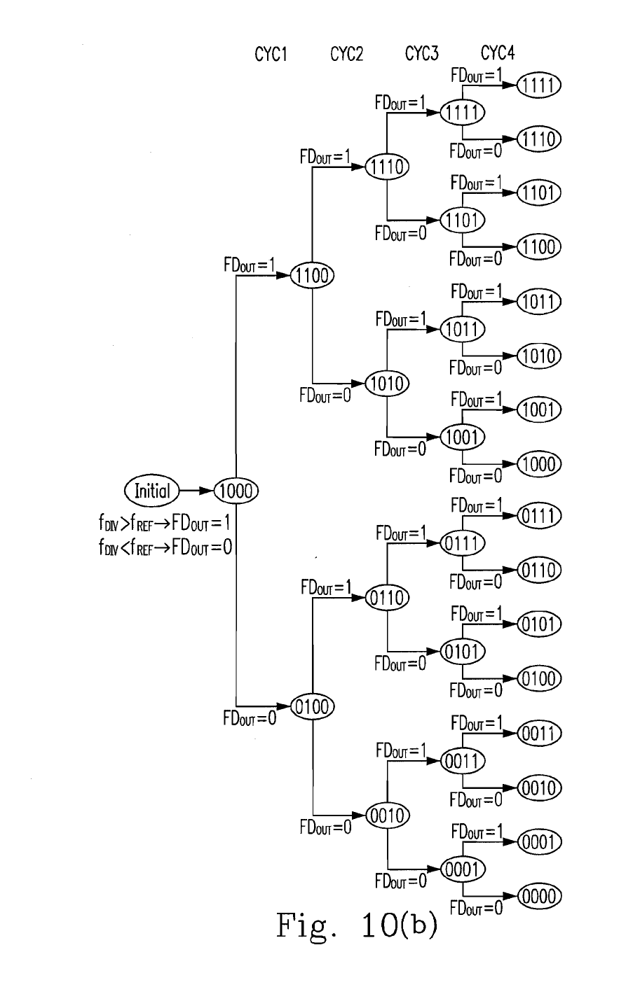

Please refer to FIG. 10(a), and FIG. 10(b), which are schematic diagrams showing a circuit of a successive approximation register controller and an algorithm thereof according to the second embodiment of the present invention, and please auxiliary refer to FIG. 6. As shown, the successive approximation register controller 524 includes four (N=4) shift registers 5240, 5241, 5242, and 5243, a flip-flop 5244, and five OR gate 5245, 5246, 5247, 5248, and 5249, receives an inverting signal of the comparison result signal FD_{OUT}, the lock result signal LD_{OUT}, the reset signal V_{RST}, and a frequency-dividing signal V_{RD1024} of the reference signal V_{REF} for producing four adjusting sub-signals V_{B3}, V_{B2}, V_{B1}, and V_{B0} of the second adjusting signal V_{ADJ2} at the four output terminals of the four shift registers 5243, 5242, 5241, and 5240 respectively, wherein the four adjusting sub-signals V_{B3}, V_{B2}, V_{B1}, and V_{B0} correspondingly control the four capacitor strings 43A0, 43A1, 43A2, and 43A3 selected or not, and form a digital adjusting value having four bits b₃, b₂, b₁, and b₀.

Afterward, the operation of the successive approximation register controller 524 is described in details. The successive approximation register controller 524 performs at most four cycling periods CYC1, CYC2, CYC3, and CYC4 of a binary search operation, and each of the four cycling periods CYC1, CYC2, CYC3, and CYC4 can form the digital adjusting value based on the comparison result signal FD_{OUT}, the lock result signal LD_{OUT}, and the reset signal V_{RST}. When the reset signal V_{RST} is in a reset state, the successive approximation register controller 524 is reset, so that the capacitor string 53A3, corresponding to the most significant bit b₃ of the four bits b₃, b₂, b₁, and b₀, of the four capacitor strings 53A3, 53A2, 53A1, and 53A0 is selected, and the other three capacitor strings 53A2, 53A1, and 53A0 corresponding to the other three bits b₂, b₁, and b₀ of the four bits b₃, b₂, b₁, and b₀ are not selected. When the lock result signal LD_{OUT} is in a non-locked state and the reset signal V_{RST} is inverted to be in a non-reset state, the successive approximation register controller 524 determines whether the four capacitor strings 53A3, 53A2, 53A1, and 53A0 are selected in an order beginning from the most significant bit b₃ of the four bits b₃, b₂, b₁, and b₀ by the comparison result signal FD_{OUT} and the binary search operation in the four cycling periods CYC1, CYC2, CYC3, and CYC4.

When the lock result signal LD_{OUT} is in the non-locked state and the reset signal V_{RST} is in the non-reset state, the successive approximation register controller 524 selects a capacitor string (such as 53A2) corresponding to each cycling period (such as CYC2) from the four capacitor strings 53A3, 53A2, 53A1, and 53A0 in advance in the each cycling period (such as CYC2) of the four cycling periods CYC1, CYC2, CYC3, and CYC4. After a pre-comparison period of the each cycling period (such as CYC2), when the comparison result signal FD_{OUT} shows that the frequency f_{DIV} of the first feedback signal V_{DIV} is greater than the frequency f_{REF} of the reference signal V_{REF}, the successive approximation register controller 524 confirms having selected the capacitor string (such as 53A2) through a corresponding adjusting sub-signal (such as V_{B2}) thereof. After the pre-comparison period of the each cycling period (such as CYC2), when the comparison result signal FD_{OUT} shows that the frequency f_{DIV} is less than the frequency f_{REF}, the successive approximation register controller 524 confirms no selection of the capacitor string (such as 53A2) through the corresponding adjusting sub-signal (such as V_{B2}) thereof.

When the reset signal V_{RST} is in the non-reset state and the lock result signal LD_{OUT} is inverted to be in a locked state, the successive approximation register controller 524 stops performing the binary search operation and holds four selection states of the four capacitor strings 53A3, 53A2, 53A1, and 53A0. Besides, when the reset signal V_{RST} is in the non-reset state and the four cycling periods CYC1, CYC2, CYC3, and CYC4 end, the successive approximation register controller 524 stops performing the binary search operation and holds the four selection states of the four capacitor strings 53A3, 53A2, 53A1, and 53A0.

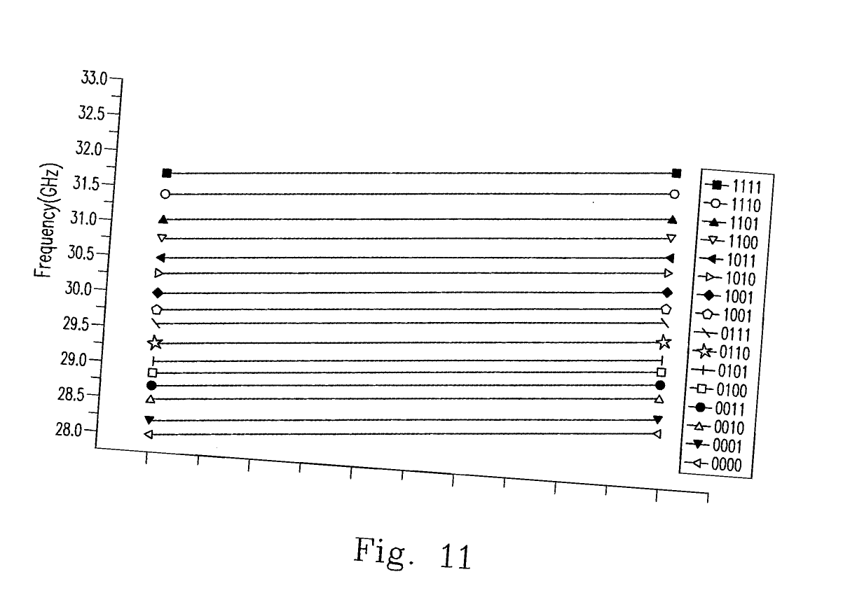

Please refer to FIG. 11, which is a schematic diagram showing a distribution of frequency bands of the phase-locked loop according to the second embodiment of the present invention. As shown, sixteen frequency bands correspond to all sixteen digital values of the four bits b₃, b₂, b₁, and b₀. The locking-range of each frequency band is about 1 GHz and the each frequency band covers about 800 MHz with its nearby frequency bands.

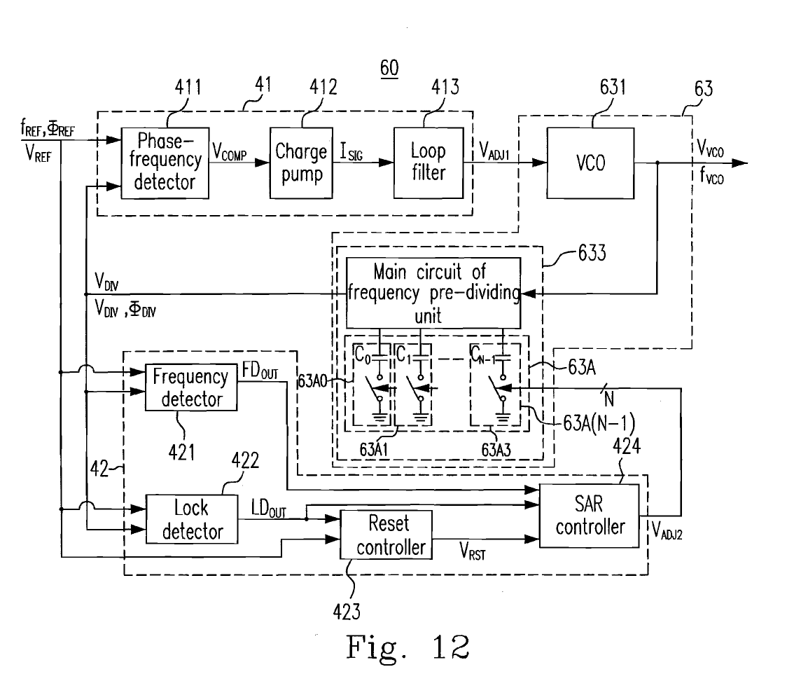

Please refer to FIG. 12, which is a schematic block diagram showing a phase-locked loop according to the third embodiment of the present invention. The circuit in FIG. 12 is based on the circuit 40 in FIG. 3 and has changed the original oscillation feedback unit 43, and the identical reference numerals have the same functions in the two figures. The phase-locked loop 60 in FIG. 12 includes the phase-voltage conversion unit 41, the calibration unit 42, and an oscillation feedback unit 63. Only the oscillation feedback unit 63 is described as follows.

The oscillation feedback unit 63 includes a voltage controlled oscillator 631, and a frequency dividing unit 633. The voltage controlled oscillator 631 receives the first adjusting signal V_{ADJ1} for producing a first object signal V_{VCO} having a frequency f_{VCO} depending on an amplitude of the first adjusting signal V_{ADJ1}. The frequency dividing unit 633 receives the first object signal V_{VCO} and dividing the frequency f_{VCO} of the first object signal V_{VCO} for producing the second feedback signal, wherein a relation of a division ratio is formed by the frequency of the second feedback signal relative to the frequency f_{VCO} of the first object signal V_{VCO}. Besides, the second feedback signal is fed back to the phase-voltage conversion unit 41 and the calibration unit 42 and is produced for serving as the first feedback signal V_{DIV}.

One of the oscillation devices, the voltage controlled oscillator 631, and the frequency dividing unit 633 includes a controllable capacitor array 63A. When the voltage controlled oscillator 631 includes the controllable capacitor array 63A, the frequency f_{VCO} of the first object signal V_{VCO} further depends on the second adjusting signal V_{ADJ2}. As shown in FIG. 12, when the frequency dividing unit 633 includes the controllable capacitor array 63A, the frequency of the second feedback signal further depends on the second adjusting signal V_{ADJ2}. The controllable capacitor array 63A includes N capacitor strings 63A0, 63A1, . . . , and 63A(N−1) correspondingly controlled by N adjusting sub-signals of the second adjusting signal V_{ADJ2} produced by the calibration unit 42, wherein N is a natural number.

Afterward, please refer to FIG. 2 again. A frequency calibration method on a phase-locked loop 30 having a controllable capacitor array 33A is described according to the present invention. The method includes the following steps. A first adjusting signal V_{ADJ1} is produced based on a frequency f_{REF} and a phase Φ_{REF} of a reference signal V_{REF}, and a frequency f_{DIV} and a phase Φ_{DIV} of a first feedback signal V_{DIV}. A second adjusting signal V_{ADJ2} is produced based on a frequency difference between the frequency f_{REF} and the frequency f_{DIV} through a binary search operation. An oscillation and a second feedback signal having a phase locked to the first phase is produced.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A phase-locked loop, comprising:
a phase-voltage conversion unit receiving a reference signal having a first frequency and a first phase, and a conversion feedback signal being a first feedback signal having a second frequency and a second phase, and producing a first adjusting signal based on the first frequency, the second frequency, and a phase difference between the first phase and the second phase;
a calibration unit receiving the reference signal and the first feedback signal, and producing a second adjusting signal based on a frequency difference between the first frequency and the second frequency through a binary search operation; and
an oscillation feedback unit receiving the first adjusting signal and the second adjusting signal, and having a controllable capacitor array controlled by the second adjusting signal for producing a second feedback signal having a third phase locked to the first phase.

2. A phase-locked loop according to claim 1, wherein the phase-voltage conversion unit further comprises:
a phase-frequency detector receiving the reference signal and the first feedback signal, and making a comparison among the first frequency, the second frequency, the first phase, and the second phase for producing a comparison result signal;
a charge pump receiving the comparison result signal for producing a current signal; and
a loop filter receiving the current signal for producing the first adjusting signal.

3. A phase-locked loop according to claim 1, wherein the controllable capacitor array has N capacitor strings, where N is a natural number, and the calibration unit further comprises:
a frequency detector receiving the reference signal and the first feedback signal, and comparing the first frequency with the second frequency for producing a comparison result signal;
a lock detector receiving the reference signal and the first feedback signal, and comparing the first phase with the second phase for producing a lock result signal;
a reset controller receiving the reference signal and the lock result signal for producing a reset signal based on the reference signal and the lock result signal; and
a successive approximation register controller having N shift registers with N output terminals, receiving the comparison result signal, the lock result signal, and the reset signal, and performing the binary search operation for producing and holding N adjusting sub-signals of the second adjusting signal at the N output terminals respectively, wherein the N adjusting sub-signals correspondingly control the N capacitor strings and form a digital adjusting value having N bits.

4. A phase-locked loop according to claim 3, wherein:
the successive approximation register controller performs at most N cycling periods of the binary search operation, and each of the N cycling periods comprises a step of forming the digital adjusting value based on the comparison result signal, the lock result signal, and the reset signal;
when the reset signal is in a reset state, the successive approximation register controller is reset, so that a first capacitor string, corresponding to a most significant bit of the N bits, of the N capacitor strings is selected, and the other (N−1) capacitor strings corresponding to the other (N−1) bits of the N bits are not selected;
when the reset signal is in the reset state, the reset controller inverts the reset signal to be in a non-reset state through a trigger signal converted from the reference signal;
when the lock result signal is in a non-locked state and the reset signal is inverted to be in the non-reset state, the successive approximation register controller determines whether the N capacitor strings are selected in an order beginning from the most significant bit of the N bits by the comparison result signal and the binary search operation in the N cycling periods;
when the lock result signal is in the non-locked state and the reset signal is in the non-reset state, the successive approximation register controller selects a second capacitor string corresponding to each cycling period from the N capacitor strings in advance in the each cycling period of the N cycling periods;
after a pre-comparison period, when the comparison result signal shows that the second frequency is greater than the first frequency, the successive approximation register controller confirms having selected the second capacitor string through a corresponding adjusting sub-signal thereof;
after the pre-comparison period, when the comparison result signal shows that the second frequency is less than the first frequency, the successive approximation register controller confirms no selection of the second capacitor string through the corresponding adjusting sub-signal thereof;
when the reset signal is in the non-reset state and the lock result signal is inverted to be in a locked state, the successive approximation register controller stops performing the binary search operation and holds N selection states of the N capacitor strings; and
when the reset signal is in the non-reset state and the N cycling periods end, the successive approximation register controller stops performing the binary search operation and holds the N selection states of the N capacitor strings.

5. A phase-locked loop according to claim 1, wherein the oscillation feedback unit further comprises:
a voltage controlled oscillator receiving the first adjusting signal for producing a first object signal having a third frequency depending on an amplitude of the first adjusting signal;
a frequency pre-dividing unit receiving the first object signal and pre-dividing the third frequency for producing an intermediate signal; and
a frequency-dividing feedback unit receiving the intermediate signal for producing the second feedback signal having a fourth frequency, wherein:
one of the voltage controlled oscillator, the frequency pre-dividing unit, and the frequency-dividing feedback unit further comprises the controllable capacitor array;
when the voltage controlled oscillator comprises the controllable capacitor array, the controllable capacitor array is connected in parallel with two output terminals of the voltage controlled oscillator and the third frequency further depends on the second adjusting signal;
when the frequency pre-dividing unit comprises the controllable capacitor array, the controllable capacitor array is connected in parallel with two output terminals of the frequency pre-dividing unit and a frequency of the intermediate signal further depends on the second adjusting signal; and
when the frequency-dividing feedback unit comprises the controllable capacitor array, the fourth frequency further depends on the second adjusting signal.

6. A phase-locked loop according to claim 5, wherein the voltage controlled oscillator further comprises a frequency-doubling unit receiving the first object signal for producing a second object signal having a frequency twice higher than the third frequency of the first object signal.

7. A phase-locked loop according to claim 5, wherein when the frequency pre-dividing unit comprises the controllable capacitor array, the frequency pre-dividing unit further comprises a differential injection-locked frequency divider having a pair of differential input terminals and a pair of differential output terminals coupled to the two output terminals of the frequency pre-dividing unit, wherein the pair of the differential input terminals receives a pair of differential input signals of the first adjusting signal, and the pair of the differential output terminals outputs a pair of differential output signals of the intermediate signal.

8. A phase-locked loop according to claim 7, wherein a standard divisor of the differential injection-locked frequency divider is 2.

9. A phase-locked loop according to claim 5, wherein:
the controllable capacitor array further comprises N capacitor strings connected in parallel and correspondingly controlled by N adjusting sub-signals of the second adjusting signal, wherein the N adjusting sub-signals form a digital adjusting value having N bits;
each of the N capacitor strings further comprises a pair of varactors face-to-face connected in series, wherein a common cathode connection point of the pair of the varactors receives a corresponding first adjusting sub-signal of the N adjusting sub-signals and each of the varactors is a transistor having a drain terminal and a source terminal commonly connected to the common cathode connection point;
N single-side capacitance values of the N capacitor strings form a distribution of geometric series with a common ratio of 2;
a most significant bit of the N bits corresponds to a first capacitor string, having a maximum value of the N single-side capacitance values, of the N capacitor strings;
a least significant bit of the N bits corresponds to a second capacitor string, having a minimum value of the N single-side capacitance values, of the N capacitor strings;
when a second adjusting sub-signal of the N adjusting sub-signals selects a third capacitor string corresponding thereto, the fourth frequency of the second feedback signal decreases in comparison with a state of the third capacitor string when not selected; and
when the second adjusting sub-signal of the N adjusting sub-signals does not select the third capacitor string corresponding thereto, the fourth frequency increases in comparison with a state of the third capacitor string when selected.

10. A phase-locked loop according to claim 1, wherein the oscillation feedback unit further comprises:
a voltage controlled oscillator receiving the first adjusting signal for producing a first object signal having a third frequency depending on an amplitude of the first adjusting signal; and
a frequency dividing unit receiving the first object signal and dividing the third frequency for producing the second feedback signal having a fourth frequency, wherein:
one of the voltage controlled oscillator, and the frequency dividing unit further comprises the controllable capacitor array;
when the voltage controlled oscillator comprises the controllable capacitor array, the third frequency further depends on the second adjusting signal; and
when the frequency dividing unit comprises the controllable capacitor array, the fourth frequency further depends on the second adjusting signal.

11. A phase-locked loop according to claim 1, wherein the second feedback signal is fed back to the phase-voltage conversion unit and the calibration unit and produced for serving as the conversion feedback signal.

12. A frequency calibration method on a phase-locked loop having a controllable capacitor array, comprising steps of:
(a) producing a first adjusting signal based on a first frequency and a first phase of a reference signal, and a second frequency and a second phase of a first feedback signal;
(b) producing a second adjusting signal based on a frequency difference between the first frequency and the second frequency through a binary search operation; and
(c) producing an oscillation and a second feedback signal having a third phase locked to the first phase.

13. A frequency calibration method according to claim 12, wherein the step (a) further comprises steps of:
producing a comparison result signal by making a comparison among the first frequency, the second frequency, the first phase, and the second phase;
producing a current signal by the comparison result signal; and
producing the first adjusting signal by the current signal.

14. A frequency calibration method according to claim 12, wherein the step (b) further comprises steps of:
producing a comparison result signal by comparing the first frequency with the second frequency;
producing a lock result signal by comparing the first phase with the second phase;
producing a reset signal based on the reference signal and the lock result signal; and
producing and holding N adjusting sub-signals of the second adjusting signal based on the comparison result signal, the lock result signal, the reset signal, and the binary search operation, wherein the N adjusting sub-signals correspondingly control N capacitor strings of the controllable capacitor array and form a digital adjusting value having N bits.

15. A frequency calibration method according to claim 14, further comprising steps of:
performing at most N cycling periods of the binary search operation, and each of the N cycling periods comprises a step of forming the digital adjusting value based on the comparison result signal, the lock result signal, and the reset signal;
resetting the second adjusting signal when the reset signal is in a reset state, so that a first capacitor string, corresponding to a most significant bit of the N bits, of the N capacitor strings is selected, and the other (N−1) capacitor strings corresponding to the other (N−1) bits of the N bits are not selected;
inverting the reset signal to be in a non-reset state through a trigger signal converted from the reference signal when the reset signal is in the reset state;
determining whether the N capacitor strings are selected in an order beginning from the most significant bit of the N bits by the comparison result signal and the binary search operation in the N cycling periods when the lock result signal is in a non-locked state and the reset signal is inverted to be in the non-reset state;
selecting a second capacitor string corresponding to each cycling period from the N capacitor strings in advance in the each cycling period of the N cycling periods when the lock result signal is in the non-locked state and the reset signal is in the non-reset state;
selecting the second capacitor string formally through a corresponding adjusting sub-signal thereof when the comparison result signal shows that the second frequency is greater than the first frequency after a pre-comparison period;
making no selection of the second capacitor string formally through the corresponding adjusting sub-signal thereof when the comparison result signal shows that the second frequency is less than the first frequency after the pre-comparison period;
stopping performing the binary search operation and holding N selection states of the N capacitor strings when the reset signal is in the non-reset state and the lock result signal is inverted to be in a locked state; and
stopping performing the binary search operation and holding the N selection states of the N capacitor strings when the reset signal is in the non-reset state and the N cycling periods end.

16. A frequency calibration method according to claim 12, wherein the step (c) further comprises steps of:
producing the second feedback signal by adjusting the first adjusting signal and by controlling the controllable capacitor array using the second adjusting signal;
producing the second feedback signal by an operation of the first adjusting signal based on a voltage controlled oscillation, a frequency pre-division, and a frequency-dividing feedback; and
adjusting a frequency of an output signal of an oscillation device by combining the controllable capacitor array to the oscillation device being one selected from a group consisting of a voltage controlled oscillator, a frequency pre-dividing unit, and a frequency-dividing feedback unit.

17. A frequency calibration method according to claim 16, further comprising steps of:
forming the controllable capacitor array by N capacitor strings connected in parallel with two output terminals of the oscillation device;
controlling the N capacitor strings correspondingly by N adjusting sub-signals of the second adjusting signal, wherein the N adjusting sub-signals form a digital adjusting value having N bits;
forming each of the N capacitor strings by a pair of varactors face-to-face connected in series, wherein a common cathode connection point of the pair of the varactors receives a corresponding first adjusting sub-signal of the N adjusting sub-signals and each of the varactors is a transistor having a drain terminal and a source terminal commonly connected to the common cathode connection point;
distributing N single-side capacitance values of the N capacitor strings according to a distribution of geometric series with a common ratio of 2;
correlating a most significant bit of the N bits with a first capacitor string, having a maximum value of the N single-side capacitance values, of the N capacitor strings;
correlating a least significant bit of the N bits with a second capacitor string, having a minimum value of the N single-side capacitance values, of the N capacitor strings;
decreasing a third frequency of the second feedback signal when a second adjusting sub-signal of the N adjusting sub-signals selects a third capacitor string corresponding thereto in comparison with a state of the third capacitor string when not selected; and
increasing the third frequency of the second feedback signal when the second adjusting sub-signal of the N adjusting sub-signals selects the third capacitor string corresponding thereto in comparison with a state of the third capacitor string when selected.

18. A frequency calibration method according to claim 16, wherein a standard divisor of the frequency pre-division is 2.

19. A frequency calibration method according to claim 12, further comprising steps of:
producing the first adjusting signal and the second adjusting signal by feeding back the second feedback signal as the first feedback signal.

20. A phase-locked loop, comprising:
a calibration unit receiving a reference signal and a first feedback signal, and producing an adjusting signal through a binary search operation; and
an oscillation feedback unit coupled to the calibration unit and having a controllable capacitor array controlled by the adjusting signal for producing a second feedback signal having a second phase locked to a first phase of the reference signal.
